(19) United States
(12) Patent Application Publication
(10) Pub. No.: US 2008/0083979 A1
(43) Pub. Date: Apr. 10, 2008

(54) Wafer holder and semiconductor manufacturing apparatus equipped with wafer holder

(75) Inventors: Masuhiro Natsuhara, Itami-shi (JP); Hirohiko Nakata, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/544,725

(22) Filed: Oct. 10, 2006

(51) Int. Cl. H01L 23/12

(52) U.S. Cl. 257/700; 257/706

(57) ABSTRACT

A wafer holder for a semiconductor manufacturing apparatus is provided with which a film may be evenly formed over the entire wafer surface and the incidence of particle generation is low, as well as a semiconductor manufacturing apparatus equipped with same.

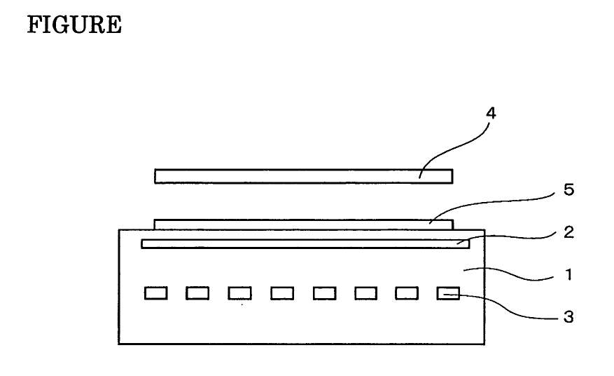

The wafer holder of the present invention is a ceramic wafer holder in which a heating body and a high-frequency electrode are embedded, and a diameter of the high-frequency electrode embedded in the ceramic is greater than the diameter of an upper high-frequency electrode disposed opposite the high-frequency electrode. A main component of the ceramic is preferably aluminum nitride, and the high-frequency electrode is preferably in the form of a film.

### BACKGROUND OF THE INVENTION

1. Field of the Invention

The present invention relates to a wafer holder used in a semiconductor manufacturing apparatus such as an etching device, a sputtering device, a plasma CVD device, a low-pressure plasma CVD device, a metal CVD device, an insulating film CVD device, a low-dielectric constant (low-K) film CVD device, a MOCVD device, a degassing device, an ion-injection device, a coater development device, and the like. The present invention particularly relates to a plasma-generating high-frequency electrode circuit formed in the wafer holder, and a treatment chamber or a semiconductor manufacturing apparatus equipped with such wafer holder.

2. Description of the Background Art

Semiconductor substrates (wafers) to be treated have conventionally been subjected to a variety of treatments in the semiconductor manufacturing step such as film-forming and etching treatments and the like. In semiconductor manufacturing apparatuses with which semiconductor substrates are subjected to such treatments, the semiconductor substrate is held in a ceramic heater for heating the substrate. As is especially so in ceramic heaters used for film-forming treatments, a reaction gas is introduced into a film-forming apparatus, and, in order for the reaction gas to be changed into plasma, a high-frequency generating electrode circuit is provided in the heater in addition to a resistive heater circuit used for heating, and a high frequency is generated between the high-frequency generating electrode circuit and an electrode disposed opposite the ceramic heater (wafer holder).

For example, such conventional ceramic heater is disclosed in Japanese Laid-Open Patent Publication No. 11-026192. The ceramic heater disclosed therein is provided with a substrate comprising a dense ceramic and an electrode embedded in the substrate, with the minimum gap between the electrode and the wafer holding surface being 0.1 mm or greater. More preferably, the gap is 0.5 mm or greater and 5 mm or less, and the electrode is a metal-bulk sheet.

The conventional ceramic heater is configured as described above so that particles are prevented from being generated by the reaction between the substrate and the reaction gas introduced into the semiconductor manufacturing apparatus. However, particles are not generated only as a result of a reaction between the reaction gas and the substrate. A film will inevitably form on other regions of the wafer, e.g., the wafer holding surface, and particles may also be formed as a result thereof.

Moreover, a diameter of the wafer has been increasing recently, and the diameter of Si wafers, for example, has increased from 8 inches to 12 inches. In the conventional wafer holder of the above reference, the increase in diameter has been accompanied by an inevitable decrease in the likelihood of plasma being generated uniformly over the entire wafer surface, so that variation occurs in the thickness or other attributes of the film formed on the outer peripheral region of the wafer, leading to a reduction in yield.

### SUMMARY OF THE INVENTION

The present invention is intended to overcome the aforedescribed problems. In other words, it is an object of the present invention to provide a wafer holder for a semiconductor manufacturing apparatus with which a film can be evenly formed over the entire wafer surface and the incidence of particle generation is low, as well as a semiconductor manufacturing apparatus equipped with the wafer holder.

The present invention was arrived at based on the discovery that the aforesaid object could be accomplished by redefining the relationship between the diameter of the high-frequency electrode circuit formed in the interior of the wafer holder and the diameter of the opposing upper high-frequency electrode. Specifically, the wafer holder of the present invention is a ceramic wafer holder in which a heating body and a high-frequency electrode are embedded. A diameter of the high-frequency electrode embedded in the ceramic is greater than the diameter of an upper high-frequency electrode disposed opposite the high-frequency electrode.

A main component of the ceramic is preferably aluminum nitride, and the high-frequency electrode is preferably in the form of a film.

A semiconductor manufacturing apparatus equipped with such wafer holder is capable of causing the plasma needed to form a film to be uniformly generated only directly above the wafer to be treated, and is accordingly able to manufacture semiconductors at high yields.

According to the present invention, the diameter of the high-frequency electrode embedded in the ceramic is greater than the diameter of the opposing upper high-frequency electrode, thereby making it possible to minimize the generation of plasma elsewhere besides the vicinity of the wafer placement surface. A semiconductor manufacturing apparatus equipped with a wafer holder of the above description is accordingly able to reduce the incidence of film formation in regions other than the wafer, and is therefore able not only to minimize the incidence of particle formation but to manufacture semiconductors at a high yield.

### BRIEF DESCRIPTION OF THE DRAWING

[FIGURE] Cross-sectional view of a wafer holder of the present invention and an upper high-frequency electrode.

### DETAILED DESCRIPTION OF THE INVENTION

The inventors discovered that the diameter of the high-frequency electrode circuit formed in the wafer holder is preferably equal to or greater than the diameter of the opposing upper high-frequency electrode in order to cause plasma to be generated evenly over the entire wafer surface and to suppress the formation of particles.

As shown in the drawing, a wafer holder includes a ceramic 1 in which a heating body 3 and a high-frequency electrode 2 are embedded. If the diameter of the high-frequency electrode circuit 2 is less than the diameter of an opposing upper high-frequency electrode 4, the resulting plasma will not adequately cover the entirety of a wafer 5. The resulting film will accordingly tend to be less thick in the outer peripheral area of the wafer. The diameter of the high-frequency electrode circuit is preferably made larger than the diameter of the upper electrode in order for a more uniform thickness distribution to be obtained in the resulting film. In other words, if the high-frequency electrode embedded in the ceramic has a large diameter, then less of the electrical field applied to and generated on the upper high-frequency electrode will wrap around and over the lateral surfaces of the wafer holder or other areas. As a result, plasma generation can be minimized in other areas besides those of the wafer. Further, if the diameter of the high-frequency electrode embedded in the ceramic is made greater than the sum of the diameter of the upper high-frequency electrode and a distance that is twice the distance between the upper high-frequency electrode and the high-frequency electrode, the wraparound of the electrical field can be reduced still further, which is preferable.

The high-frequency electrode embedded in the ceramic may be in the configuration of a metallic mesh, but is preferably in the form of a film. If a metallic mesh is used for the high-frequency electrode embedded in the ceramic, some of the electrical field will inevitably leak from the gaps in the mesh, and a film may form in regions other than those pertaining to the wafer. However, if the electrode is in the form of a film, such leakage will not occur, which is preferable.

A ceramic is preferably used as the material for the wafer holder of the present invention. If a metal is used, a problem arises in that particles will adhere to the wafer, which is undesirable. If uniformity of temperature distribution is a priority, then aluminum nitride or silicon carbide, which have high thermal conductivity, are preferably used. If reliability is a priority, then silicon nitride is preferably used because of its high strength and resistance to thermal shock. If cost is a priority, then aluminum oxide is preferably used.

If the cost-performance balance is taken into account, aluminum nitride (AlN) is preferred among the above ceramic materials due to its high thermal conductivity and exceptional corrosion resistance. A method for manufacturing the wafer holder of the present invention using AlN shall be described in detail below.

The raw material AlN powder preferably has a specific surface area of 2.0 to 5.0 m²/g. If the specific surface area is less than 2.0 m²/g, then the aluminum nitride will have diminished sinterability. Conversely, if the specific surface area exceeds 5.0 m²/g, the powder will have an extremely high tendency to aggregate, and will become more difficult to handle. The amount of oxygen contained in the raw material powder is preferably 2 wt % (weight percent) or less. If the amount exceeds 2 wt %, the thermal conductivity of the sintered body will deteriorate. The amount of metallic impurities other than aluminum contained in the raw material powder is preferably 2000 ppm or less. If the amount thereof exceeds this range, the thermal conductivity of the sintered body will decrease. Si and other Group IV elements as well as Fe and other iron-group elements are metallic impurities that have a strong action for reducing the thermal conductivity of sintered bodies, and thus, the content of each is preferably 500 ppm or less.

AlN is a poorly sinterable material, for which reason a sintering aid is preferably added to the AlN raw material powder. The sintering aid to be added is preferably a rare-earth element compound. During sintering, the rare-earth element compound reacts with aluminum oxides or aluminum oxynitrides present on the surface of the particles of the aluminum nitride powder, thereby accelerating compaction of the aluminum nitride, as well as serving to eliminate oxygen, which causes the thermal conductivity of the aluminum nitride sintered body to decrease. The thermal conductivity of the aluminum nitride sintered body can accordingly be increased.

The rare-earth element compound is preferably an yttrium compound having a particularly dramatic ability to remove oxygen. The compound is preferably added in an amount of 0.01 to 5 wt %. If the amount is less than 0.01 wt %, complications will be encountered in obtaining a dense sintered body, and the thermal conductivity of the sintered body will decrease. If the amount exceeds 5 wt %, the sintering aid will be present in the grain boundaries within the aluminum nitride sintered body, and thus, in corrosive environments, the sintering aid present in the grain boundaries will be etched, leading to particle shedding and particle formation. The sintering aid is more preferably added in an amount of 1 wt % or less. If the amount is 1 wt % or less, none of the sintering aid will be present in the grain boundary triple point, and corrosion-resistance will improve.

Oxides, nitrides, fluorides, stearic acid compounds and the like may be used as the rare-earth element compound. Among these compounds, oxides are preferred for their low cost and ready availability. Stearic acid compounds are particularly preferred because they have a high affinity with organic solvents, and thus, will exhibit good mixing properties when the raw material aluminum nitride powder is blended with the sintering aid or the like using an organic solvent.

A prescribed amount of a solvent, binder, and, if necessary, a dispersant and antiflocculant are then added to and admixed with the aluminum nitride raw material powder and sintering aid powder. The mixing may be performed with a ball mill, ultrasound, or another method. Such methods are able to yield a raw material slurry.

The resulting slurry is molded and sintered to yield an aluminum nitride sintered body. Two types of methods, namely co-firing and post-metallizing, may be applied hereto.

Post-metallizing shall be described first. The slurry is formed into granules by spray-drying or another process. The granules are loaded into a prescribed mold, and press-molded. The pressure during this process is desirably 9.8 MPa or higher. If the pressure is less than 9.8 MPa, the molded article will often exhibit inadequate strength, and tend to break when handled or otherwise manipulated.

The density of the molded article will vary depending on the binder content and amount of sintering aid added, but is preferably 1.5 g/cm³ or higher. If the density is less than 1.5 g/cm³, the distance between the particles in the raw material powder will increase in a relative manner, thereby hindering the progress of sintering. The density of the molded article is also preferably 2.5 g/cm³ or less. If the density exceeds 2.5 g/cm³, it will become difficult to adequately remove the binder in the molded article during the degreasing treatment in the following step. As a result, a compact sintered body will become difficult to obtain, as described hereinabove.

The molded article is subsequently heated in a non-oxidizing atmosphere, and subjected to a degreasing treatment. The surface of the AlN powder will oxidize when the degreasing treatment is performed in atmospheric air or another oxidizing atmosphere, as a result of which the thermal conductivity of the sintered body will decrease. Nitrogen and argon are preferably used for the gas in the non-oxidizing atmosphere. The temperature at which heating is performed during the degreasing treatment is preferably 500° C. or higher and 1000° C. or lower. If the temperature is less than 500° C., it will be difficult to adequately remove the binder. Accordingly, an excess of carbon will remain in the layered article obtained after the degreasing treatment, which will hinder sintering in the subsequent sintering step. If the temperature exceeds 1000° C., the amount of residual carbon will become excessively low, and thus, the ability to remove oxygen from the oxidized film present on the AlN power surface will deteriorate, and the thermal conductivity of the sintered body will decrease.

The amount of carbon remaining in the molded article following the degreasing treatment is preferably 1.0 wt % or less. If more than 1.0 wt % remains in the molded article, sintering will be hindered, making it impossible for a dense sintered body to be obtained.

Sintering is subsequently performed. Sintering is performed at a temperature between 1700 and 2000° C. in a non-oxidizing atmosphere of nitrogen, argon, and the like. The moisture content of the nitrogen or other atmosphere gas employed is preferably such that the dew point is −30° C. or lower. If the moisture content exceeds this level, the AlN will react with the moisture in the atmosphere gas during sintering to form oxynitrides, which may lower thermal conductivity. The amount of oxygen in the atmosphere is preferably 0.001 vol % or less. If the amount exceeds this level, the AlN surface will oxidize, and thermal conductivity may deteriorate.

The jig used during sintering is preferably a boron nitride (BN) molded article. BN molded articles are adequately heat-resistant under the sintering temperature, and the surface thereof has solid lubricity. It is accordingly possible to reduce the friction between the jig and the layered article when the layered article shrinks during sintering, thereby allowing the resulting sintered body to have minimal distortion.

The resulting sintered body is worked as needed. If a conductive paste is to be screen-printed thereon in the subsequent step, the surface roughness (Ra) of the sintered body is preferably 5 μm or less. If the roughness exceeds 5 μm, pattern bleed, pinholing, and other defects will tend to occur when the circuit is formed via screen printing. The surface roughness (Ra) is more preferably 1 μm or less.

Polishing to reduce the surface roughness is performed when screen printing is to be performed on both sides of a sintered body, but even if screen printing is to be performed on only one side thereof, the surface on which screen printing is to be performed and the surface on the opposite side is preferably polished. If it is only the surface on which screen printing is to be performed that is to be polished, the sintered body will have to be supported on the side that is not to be polished during screen printing. This is because protrusions or foreign matter may be present on the non-polished side during this time, which may result in lack of stability when the sintered body is fixed in place, and the circuit pattern being inaccurately drawn during screen printing.

The parallelism of both worked surfaces is preferably 0.5 mm or less. If the parallelism exceeds 0.5 mm, the variation in the thickness of the conductive paste may increase during screen printing. A parallelism of 0.1 mm or less is particularly preferred. The planarity of the surface on which screen printing is to be performed is preferably 0.5 mm or less. Similarly, variation in the thickness of the conductive paste may increase if the planarity exceeds 0.5 mm. A planarity of 0.1 mm or less is also particularly preferred.

The polished sintered body is coated with a conductive paste as a result of screen printing, and an electrical circuit is formed. The conductive paste may be obtained by mixing a metallic powder with, as necessary, an oxide powder, a binder, and a solvent. The metallic powder is preferably tungsten, molybdenum, or tantalum in consideration of matching the coefficient of thermal expansion with the ceramic.

An oxide powder may also be introduced in order to increase the adhesive strength with the AlN. The oxide powder is preferably an oxide of a Group IIa or IIIa element, Al₂O₃, SiO₂, or the like. Yttrium oxide is preferable due to its very good wettability with regard to the AlN. These oxides are preferably introduced in an amount of 0.1 to 30 wt %. If the amount is less than 0.1 wt %, the adhesive strength between the AlN and the resulting metallic layer that forms the electrical circuit will decrease. If the amount exceeds 30 wt %, the electrical resistivity of the metallic layer that forms the electrical circuit will increase.

The thickness of the conductive paste after drying is preferably 5 μm or greater and 100 μm or less. If the thickness is less than 5 μm, the electrical resistivity will excessively increase, and the adhesive strength will deteriorate. If the thickness exceeds 100 μm, the adhesive strength will deteriorate.

If the resulting circuit pattern is for a heater circuit (resistive heating body circuit), the gaps between the circuit patterns are preferably 0.1 mm or more. If the gaps are less than 0.1 mm, then a leakage current will be produced depending on the applied voltage and temperature when a current is delivered to the resistive heating body, and circuit shorting is caused. In environments where a temperature of 500° C. or more is used, the pattern gap is preferably 1 mm or greater, and more preferably 3 mm or greater.

The conductive paste is degreased and subsequently calcined. The degreasing is performed in a non-oxidizing atmosphere of nitrogen, argon, or another gas. The degreasing temperature is preferably 500° C. or higher. If the temperature is less than 500° C., the binder within the conductive paste will be inadequately removed, carbon will remain within the metallic layer, and metal carbides will be formed during calcination. As a result, the electrical resistivity of the metallic layer will increase.

Calcining is preferably performed at a temperature of 1500° C. or higher in a non-oxidizing atmosphere of nitrogen, argon, or another gas. If the temperature is less than 1500° C., the grains of the metallic powder within the conductive paste will not proceed to grow, and the electrical resistivity of the metallic layer after sintering will excessively increase as a result. The calcining temperature should not exceed the ceramic sintering temperature. If the conductive paste is calcined at a temperature that exceeds the ceramic sintering temperature, the sintering aid and other components of the ceramic will start to sublimate, the growth of the grains within the metallic powder in the conductive paste will be accelerated, and the adhesive strength between the ceramic and the metallic layer will deteriorate.

In order to ensure the insulating properties of the resulting metallic layer, an insulating coat may be formed thereon. The insulating coat is preferably of the same material as the ceramic on which the metallic layer has been formed. If there is a substantial difference between the material used for the insulating coat and the ceramic, warping will occur after sintering and other problems will arise due to the difference in the coefficients of thermal expansion. Using AlN by way of example, a prescribed amount of an oxide or carboxide of a Group IIa or IIIa element is added to and admixed with the AlN powder as a sintering aid, a binder and solvent are added to the resulting mixture to form a paste, and the paste can be applied on the metallic layer via screen printing.

The amount of sintering aid to be added during this process is preferably 0.01 wt % or more. If the amount is less than 0.01 wt %, a dense insulating coat will not be obtained, and difficulties will be encountered in assuring the insulating properties of the metallic layer. The sintering aid is also preferably not added in an amount exceeding 20 wt %. If the amount exceeds 20 wt %, an excess of the sintering aid will penetrate into the metallic layer, thereby inevitably changing the electrical resistivity thereof. There are no particular limitations as to the thickness of the coat, but a thickness of 5 μm or more is preferable since difficulties will be presented in maintaining the insulating properties at thicknesses of less than 5 μm.

A ceramic substrate may then be layered if required. Layering may be performed with a bonding agent. The bonding agent is obtained by adding a binder, solvent, and a Group IIa or Group IIIa element compound to an aluminum oxide power or an aluminum nitride powder and forming the resulting mixture into a paste, and this paste is applied to the bonding surface by screen printing or another technique. There are no particular limitations as to the thickness of the applied bonding agent, but the thickness is preferably 5 μm or more. If the thickness is less than 5 μm, then pinholing, uneven bonding and other related defects will tend to occur in the bonding layer.

The ceramic substrate on which the bonding agent has been coated is degreased at a temperature of 500° C. or more in a non-oxidizing atmosphere. The ceramic substrates are then layered, subjected to a prescribed load, and heated in a non-oxidizing atmosphere to be bonded together. The load is preferably 5 kPa or higher. If the load is less than 5 kPa, adequate bonding strength will not be obtained, or the aforedescribed bonding defects will tend to occur.

There are no particular limitations as to the heating temperature required for bonding purposes provided that the ceramic substrates can be adequately bonded with the bonding layer interposed therebetween, However, a temperature of 1500° C. or higher is preferable. If the temperature is less than 1500° C., adequate bonding strength will not be readily obtained, and bonding-related defects will tend to occur. Nitrogen and argon are examples of gases to be used in the non-oxidizing atmosphere in which degreasing and bonding are performed.

A layered sintered ceramic body for use as a wafer holder may be obtained as described in the foregoing. A conductive paste does not have to be used for the electrical circuits. For example, molybdenum wires (coils) can also be used with heater circuits, and molybdenum or tungsten meshes (netlike pieces) can be used with circuits for electrostatic adsorption, electrode circuits for high-frequency generation, or the like.

In such instances, the molybdenum coil or mesh is disposed within the AlN raw material powder, and the article can be fabricated by a hot-press method. The temperature and atmosphere employed when a hot press is used are preferably in accordance with the temperature and atmosphere used for sintering the AlN, but the pressure applied with the hot press is preferably 1 MPa or higher. If the pressure is less than 1 MPa, then gaps may form between the AlN and the molybdenum coil or mesh, which may prevent the heater from working.

The co-firing method shall be described hereunder. The raw material slurry described hereinabove is molded into a sheet using a doctor blade method. There are no particular limitations as to the conditions applying when the sheet is molded, but the sheet thickness is preferably 3 mm or less after drying. If the sheet thickness is more than 3 mm, the amount of dry shrinkage in the slurry will increase, which will raise the likelihood of cracking in the sheet.

The metallic layer that will become the electrical circuit of a prescribed shape is formed on the aforedescribed sheet by applying a conductive paste using screen printing or another technique. The conductive paste may be the same as the one described for the post-metallizing process. However, in co-firing, an oxide power need not be added to the conductive paste.

The sheet on which a circuit has been formed and the sheet on which a circuit has not been formed are then layered. The sheets are layered by being placed in prescribed positions and then layered. A solvent may be applied between the sheets if necessary. Heating may be applied to the layered sheets if necessary, in which case the heating temperature is preferably 150° C. or less. If heating is performed at a higher temperature, then the layered sheet will substantially deform. Pressure is applied to the layered sheets to produce an integrated assembly. The applied pressure is preferably in a range of 1 to 100 MPa. If the pressure is less than 1 MPa, then the sheets will not adequately form into an integrated assembly, and may separate during a subsequent step. If a pressure exceeding 100 MPa is applied, the sheets will deform to an excessive degree.

The layered article is then subjected to a degreasing treatment and sintering in the same manner as performed with post-metallizing, as described hereinabove. When the conductive paste is imprinted on the sheets as described above, the heater circuit, electrostatic adsorption circuit, and the like are printed on the plurality of sheets, which are then layered together. Therefore, it is possible to readily produce a wafer holder having a plurality of electrical circuits. Accordingly, it is possible to obtain a ceramic layered sintered body that will be the wafer holder main body.

The resulting ceramic layered sintered body may be worked if necessary. The sintered body is not often suited to the level of precision required for semiconductor manufacturing apparatuses. The working precision preferably requires, e.g., the planarity of the wafer mounting surface to be 0.5 mm or less, and more preferably 0.1 mm or less. If the planarity exceeds 0.5 mm, gaps will tend to form between the wafer and the wafer holder and heat from the wafer holder will not be uniformly relayed to the object to be treated, so that the object to be treated will tend to be subjected to uneven temperatures.

The surface roughness (Ra) of the wafer holding surface is preferably 5 μm or less. If the Ra exceeds 5 μm, then the friction produced between the wafer holder and the wafer will often cause the AlN to be shed as particles. The resulting particles end up having an adverse effect during the forming of films on the wafer, etching, and other treatments. The surface, roughness (Ra) is more preferably 1 μm or less.

The wafer holder main body may be fabricated as described in the foregoing. A shaft is also mounted to the wafer holder. There are no particular limitations as to the material used for the shaft provided that the coefficient of thermal expansion of the material is not substantially different from that of the ceramic of the wafer holder. The difference in coefficient of thermal expansion with respect to the heater part is preferably 5×10⁻⁶ K or less.

If the difference in the coefficient of thermal expansion is more than 5×10⁻⁶ K, then cracks or other defects will appear in the vicinity of the bond between the wafer holder and the shaft during mounting, and even if cracks do not form during bonding, the bond region will be subjected to a heat cycle during repeated use, which may result in breaking or the formation of cracks. For example, if the wafer holder is made of AlN, the shaft material will ideally be AlN, but silicon nitride, silicon carbide, or mullite may also be used.

The shaft is bonded via a bonding layer. The bonding layer preferably comprises AlN and Al₂O₃ along with a rare-earth oxide. These components exhibit excellent wettability with AlN and other ceramic materials used for the wafer holder and the shaft, thereby resulting in high bonding strength and airtightness readily obtained on the bonding surfaces, which is preferable.

The planarity of the bonding surfaces of the shaft and wafer holder to be joined is preferably 0.5 mm or less. If the planarity exceeds this level, gaps will tend to form on the bonding surfaces, and the bond will tend not to have adequate airtightness. The planarity is more preferably 0.1 mm or less. The planarity of the wafer holder bonding surface is still more preferably 0.02 mm or less. The roughness (Ra) of each bonding surface is preferably 5 μm or less. If the roughness exceeds this level, gaps will similarly form in the bonding surfaces. The surface roughness (Ra) is more preferably 1 μm or less.

An electrode is subsequently mounted to the wafer holder. The mounting can be performed via a well-known method. For example, end milling is performed from the side opposite the wafer-holding surface of the wafer holder to the electrical circuit, and an electrode made from molybdenum, tungsten, or another material may be connected to the electrical circuit using metallizing or directly with an active metal wax without metallizing being performed. If necessary, the electrode can subsequently be plated in order to improve its oxidation resistance. A wafer holder for a semiconductor manufacturing apparatus can accordingly be fabricated.

If the wafer holder of the present invention for forming high-frequency generating electrode circuits is mounted on a semiconductor manufacturing apparatus and a film is formed on a wafer, the film can be uniformly formed thereon, and few particles will be produced by the resulting semiconductor manufacturing apparatus. Using the wafer holder of the present invention results in little incidence of particle formation, while the plasma density is obtained uniformly over the entire wafer surface. It is accordingly possible to obtain films with stable characteristics.

### WORKING EXAMPLE 1

A quantity of 1.0 weight parts of Y₂O₃ was added to 99 weight parts of an aluminum nitride (AlN) powder. Using polyvinyl butyral as a binder and dibutyl phthalate as a solvent, these components were blended in amounts of 10 weight parts and 5 weight parts, respectively. A doctor blade method was used to mold a 1.3 mm-thick green sheet. The aluminum nitride powder had an average particle size of 0.6 μm and a specific surface area of 3.4 m²/g.

Using a quantity of 100 weight parts of a W powder having an average particle size of 2.0 μm, 1 weight part of Y₂O₃, 5 weight parts of ethyl cellulose as a binder, and butyl carbitol as a solvent were used to form a W paste. The components were mixed using a pot mill and three rolls. The W paste was screen-printed on the green sheet to form a high-frequency generating electrode circuit patterns. The diameters of the circuit patterns are shown in Table 1. A resistive heater circuit pattern was screen-printed on a separate green sheet. The green sheets were layered together, degreased at 800° C. in a nitrogen atmosphere, and calcined at 1850° C. in a nitrogen atmosphere.

Polishing was performed after sintering so that the wafer holding surface had an Ra of 1 μm or less and the joining surface of the holding part had an Ra of 5 μm or less. The outer diameter was finished to 360 mm.

The wafer holders shown in Table 1 were used to form W films on a Si wafer with a diameter of 300 mm. The diameter of the opposite upper high-frequency electrode was 300 mm, and the distance relative to the high-frequency electrode of the wafer holder was 10 mm. WF₆, SiH₄ and H₂ were introduced as reaction gases. A high frequency was applied to the electrode for the high-frequency generating electrode circuit, thereby producing a plasma and forming a W film on the Si wafer.

Once the film had been formed, the state of film formation elsewhere besides the wafer was observed. The thickness of the resulting W film was measured using a fluorescent X-ray film thickness meter, and the results are shown in Table 1. “◯” indicates uniform film thickness distribution, “Δ” indicates a relatively high thickness distribution, but not to the extent of preventing practical application, and “X” indicates that practical application was impossible due to excessively high thickness distribution. The formation of a film elsewhere besides the wafer was categorized as “⊙” if no or substantially no film had formed, “◯” if some film formation was observed but not to the extent of preventing practical application, “Δ” if film formation was evident and particle formation occurred to the extent of being of some concern, and “X” if a film had formed to the same degree as on the wafer. The results are displayed in Table 1.

TABLE 1

| | Diameter of | | Formation of |
|---|---|---|---|
| | high-frequency | Thickness | film elsewhere |
| No. | electrode (mm) | distribution | besides the wafer |
| 1 | 280 | Δ | Δ |
| 2 | 300 | ◯ | ◯ |
| 3 | 310 | ◯ | ◯ |
| 4 | 320 | ◯ | ⊙ |
| 5 | 330 | ◯ | ⊙ |
| 6 | 350 | ◯ | ⊙ |

### WORKING EXAMPLE 2

A quantity of 1.0 weight parts of Y₂O₃ was added to 99 weight parts of an aluminum nitride (AlN) powder. Using polyvinyl butyral as a binder and dibutyl phthalate as a solvent, these components were blended in amounts of 10 weight parts and 5 weight parts, respectively, to form a slurry. The slurry was spray-dried to form a granular powder product. The powder product was placed in a press mold, 80-mesh molybdenum was inserted as a high-frequency electrode circuit, and more of the powder product was placed in the mold, after which a molybdenum coil to be used as a heating body was co-embedded therein. The contents were press-molded into a molded article, and the article was hot-pressed under a 200 ton load at 1850° C. in a nitrogen atmosphere to form a wafer holder. W films were formed in the same manner as in Working Example 1, and subsequently evaluated. The results are displayed in Table 2.

TABLE 2

| | Diameter of | | Formation of |
|---|---|---|---|
| | high-frequency | Thickness | film elsewhere |
| No. | electrode (mm) | distribution | besides the wafer |
| 7 | 280 | X | X |
| 8 | 300 | Δ | Δ |
| 9 | 310 | Δ | Δ |
| 10 | 320 | ◯ | ◯ |
| 11 | 330 | ◯ | ◯ |
| 12 | 350 | ◯ | ◯ |

As is evident from Working Examples 1 and 2, when the diameters of the high-frequency electrodes embedded in the ceramic were made larger than the diameter of the opposing upper high-frequency electrode, a better thickness distribution was obtained, and there was less incidence of film formation elsewhere besides the wafer. It was also evident that when the high-frequency electrode embedded in the ceramic was fashioned into the form of a film, the incidence of film formation elsewhere besides the wafer was even less.

According to the present invention, the diameter of a high-frequency electrode embedded in a ceramic is greater than the diameter of the opposing upper high-frequency electrode. It is accordingly possible to minimize the generation of plasma elsewhere beyond the vicinity of the surface where the wafer is placed. Accordingly, the formation of films elsewhere besides on the wafer is minimized in semiconductor manufacturing apparatuses equipped with such a wafer holder, which enables the formation of particles to be minimized and semiconductors to be manufactured in good yields.

What is claimed is:

1. A wafer holder comprising:
a ceramic substrate having a heating body embedded therein, and configured and arranged to be disposed facing an upper high-frequency electrode; and
a high-frequency electrode embedded in the ceramic substrate having a diameter that is equal to or greater than a diameter of the upper high-frequency electrode disposed opposite the high-frequency electrode.

2. The wafer holder according to claim 1, wherein
a main component of the ceramic substrate is aluminum nitride.

3. The wafer holder according to claim 1, wherein
the high-frequency electrode is formed as a film.

4. A semiconductor manufacturing apparatus including the wafer holder according to any one of claims 1 through 3.
